(19) United States
(12) Patent Application Publication
(10) Pub. No.: US 2005/0263901 A1
(43) Pub. Date: Dec. 1, 2005

(54) SEMICONDUCTOR DEVICE FORMED BY IN-SITU MODIFICATION OF DIELECTRIC LAYER AND RELATED METHODS

(75) Inventor: William G. America, Kingston, NY (US)

Correspondence Address: HOFFMAN WARNICK & D'ALESSANDRO, LLC, 75 STATE STREET, 14TH FL, ALBANY, NY, 12207, US

(73) Assignee: INTERNATIONAL BUSINESS MACHINES CORPORATION, Armonk, NY (US)

(21) Appl. No.: 10/709,776

(22) Filed: May 27, 2004

(51) Int. Cl. H01L 23/48

(52) U.S. Cl. 257/760

(57) ABSTRACT

Disclosed is a semiconductor device with a continuously-deposited dielectric layer having different etch resistances through its depth and methods of manufacturing such a device. Specifically, differing etch resistances in the dielectric layer are obtained by modifying the composition of the dielectric layer, the deposition conditions, or both, during deposition of the dielectric layer. The disclosed device and methods eliminate the depth and resistance variations inherent in time-based etch techniques and enable the deposition of a dielectric layer with varying etch resistances in a single deposition step.

### BACKGROUND OF INVENTION

(1) Technical Field

The present invention relates generally to the manufacture of semiconductor devices and more particularly to the in-situ modification of a dielectric layer to form an etchstop.

(2) Related Art

In the manufacture of semiconductor devices, it is usually necessary to construct openings of different depths into a dielectric layer. Vertical openings, such as vias, extend downward through the dielectric layer to contact a substrate. Horizontal openings, such as troughs, extend partially into a dielectric layer along an essentially horizontal pathway.

As the openings for vias and troughs extend into the di-electric layer to different depths, it is necessary to be able to etch the dielectric layer to different depths. One approach for doing this process is time-based plasma etching, in which, for example, openings for vias are etched for a longer period than are the shallower openings for troughs. A significant drawback to such a method is the amount of variation in trough depth. Variations in the thickness of the dielectric layer itself are compounded by variations in the rate at which the dielectric layer is etched. Such variations lead not only to variations in the resistance of the final conductive line of the semiconductor device, but to variations in the resistances of conductive lines among different semiconductor devices.

Another approach for etching a dielectric layer to different depths is the deposition of the dielectric material in discrete layers. Generally, a dielectric material is deposited to a fraction of the desired thickness of the dielectric layer, then a thin etch-resistant layer is deposited, and, finally, the original dielectric material is again deposited until the dielectric layer reaches its desired thickness. Such methods suffer from two major drawbacks. First, deposition of each of these layers is discrete, requiring stoppage of the deposition between layers. Second, the etch-resistant layer is usually a silicon nitride or silicon carbide, which increases the overall dielectric constant of the dielectric layer.

Thus, there remains a need for a method of creating openings of different depths in a dielectric layer that does not require reliance on time-based etching techniques or formation of the dielectric layer by deposition of discrete layers.

### SUMMARY OF INVENTION

The invention includes a semiconductor device with a continuously-deposited dielectric layer having different etch resistances through its depth and methods of manufacturing such a device. Specifically, differing etch resistances in the dielectric layer are obtained by modifying the composition of the dielectric layer, the deposition conditions, or both, during deposition of the dielectric layer. The disclosed device and methods eliminate the depth and resistance variations inherent in time-based etch techniques and enable the deposition of a dielectric layer with varying etch resistances in a single deposition step.

A first aspect of the invention is directed toward a semiconductor device comprising a substrate; a dielectric layer atop the substrate, the dielectric layer including a first sub-layer, a second sub-layer and a non-discrete transitional sub-layer residing between the first and second sub-layer, wherein the first sublayer has an etch resistance different than the second sub-layer; and an opening extending no deeper than the sub-layer nearest the substrate.

A second aspect of the invention is directed toward a method of modifying a dielectric composition during deposition, the method comprising the steps of continuously depositing a dielectric layer onto a substrate; and modifying at least one of a dielectric layer composition and a deposition condition during the depositing step.

A third aspect of the invention is directed toward a method of forming at least one opening in a dielectric layer, the method comprising the steps of continuously depositing a dielectric layer onto a substrate; modifying at least one of the dielectric layer composition and a deposition condition; and forming an opening in the dielectric layer.

The foregoing and other features of the invention will be apparent from the following more particular description of embodiments of the invention.

### BRIEF DESCRIPTION OF DRAWINGS

The embodiments of this invention will be described in detail, with reference to the following figures, wherein like designations denote like elements, and wherein:

FIGS. 1-3 show schematic cross-section views of steps of forming a semiconductor device according to a first embodiment of the invention.

FIGS. 4-5B show schematic cross-section views of steps of forming an opening in a semiconductor device according to a first embodiment of the invention.

FIGS. 6-7 show schematic cross-section views of steps of forming a semiconductor device according to a second embodiment of the invention.

FIGS. 8-9B show schematic cross-section views of steps of forming an opening in a semiconductor device according to a second embodiment of the invention.

### DETAILED DESCRIPTION

In general, the device and methods of the claimed invention employ terminologies common to the manufacture of semiconductor devices. For example, unless stated more specifically, an “opening”, as used in the following description and claims, may be a channel, via, hole, socket, valley, furrow, trough, duct, trench, or any other similar structure. Similarly, deposition of a dielectric layer and formation of openings in a dielectric layer may be by any means now known or later developed.

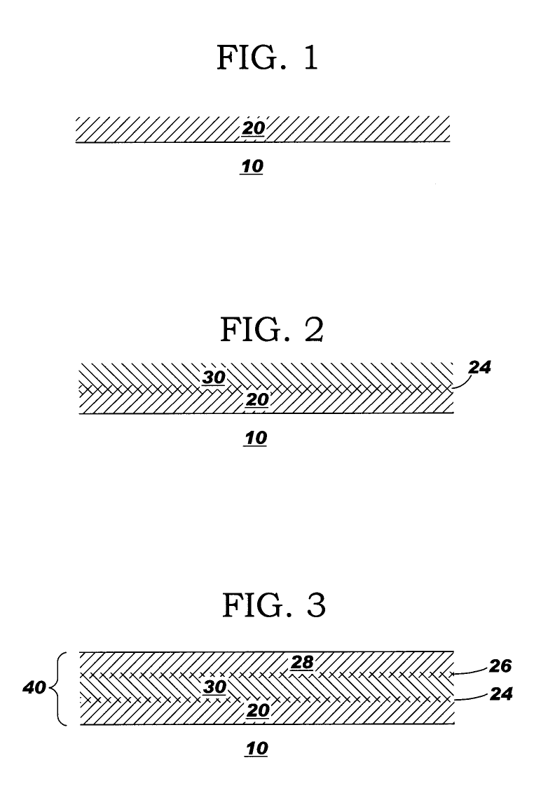

FIGS. 1-3 illustrate steps in the formation of a semiconductor device according to a first embodiment of the invention. Referring to FIG. 1, a first dielectric sub-layer 20 has been deposited onto a substrate 10. First dielectric sub-layer 20 can be of any material common to the manufacture of semiconductor devices, such as, silicon oxide (SiO), silicon dioxide (SiO₂), hydrogenated silicon oxycarbide (SiCOH), etc.

Referring to FIG. 2, without stopping the deposition of the dielectric layer, the etch properties of the dielectric layer are altered by modifying the components of the dielectric layer, or the deposition conditions, or both. “Deposition conditions” are any environmental or mechanical conditions capable of affecting the deposition of the dielectric layer, including, e.g., temperature, pressure, flow rate of dielectric layer components, and plasma power. The resulting second dielectric sub-layer 30 has etch properties different than first dielectric sub-layer 20. The interface between first dielectric sub-layer 20 and second dielectric sub-layer 30 is distinguished by a first non-discrete transitional sub-layer 24. The composition of first non-discrete transitional sub-layer 24 varies through its thickness from a composition substantially the same as first dielectric sub-layer 20 where it contacts first dielectric sub-layer 20 to a composition substantially the same as second dielectric sub-layer 30 where it contacts second dielectric sub-layer 30, the change in composition being gradual within first non-discrete transitional sub-layer 24.

In one embodiment, second dielectric sub-layer 30 is more etch resistant than first dielectric sub-layer 20, effectively forming an etch stop layer within the dielectric layer. In one embodiment, etch resistance is increased in second dielectric sub-layer 30 by, for example, increasing its carbon content, or fluorine content, or both. An increase in carbon content results, for example, in a general reduction in etch rate. And, since typical etch processes use fluorocarbon gasses, such as, tetrafluoromethane (CF₄), trifluoromethane (CHF₃), difluoromethane (CH₂F₂), perfluorobutene (C₄F₈), etc., the substitution of fluorine atoms for hydrogen atoms in the dielectric layer will similarly result in a reduced etch rate. Thus, an increase in etch resistance and formation of an etch stop layer can be achieved by modifying the composition of the dielectric layer, or the deposition conditions, or both.

In one embodiment, modification of the composition of the dielectric layer includes the addition of organic alkoxysilanes, alkylsiloxanes, and their fluoro-substituted analogs. In one embodiment of the invention, such compounds may include, for example, methylsilane, dimethylsilane, trimethylsilane, trifluoromethylsilane, 1,2-disilanotetrafluorethylene, 1,3-bis(silanodifluoromethylene)disiloxane, 2,2-disilanohexafluorosilane, bis(trifluoromethyldisiloxanyl)difluormethane, octamethylcyclotetrasiloxane, and tetramethylcyclotetrasiloxane. It should be recognized that the above list is not exhaustive.

Modification of the deposition conditions includes changes to, for example, temperature, pressure, flow rate of dielectric layer components, and plasma power. In one embodiment, useful ranges of such conditions include, for example, a temperature range of −20° C. to 400° C.; a pressure range of 1 to 3 Torr; flow rates of 10 to 50 standard cubic centemeters per minute (sccm) for a carbon source or fluorocarbon source, 300 to 500 sccm for an oxidizer, such as, oxygen (O₂), nitrogen dioxide (NO₂), etc., and 1500 to 2500 sccm for an inert gas, such as, helium (He), argon (Ar), etc.; and a plasma power range of 20 to 500 Watts. The above ranges are provide for purposes of illustration only and are not meant to be limiting.

Referring to FIG. 3, without stopping the deposition of the dielectric layer, the etch properties of the dielectric layer may again be altered by modifying the components of the dielectric layer, or the deposition conditions, or both. Generally, the components of the dielectric layer, the deposition conditions, or both, are returned to their initial states, resulting in a third dielectric sub-layer 28 with etch properties substantially the same as first dielectric sub-layer 20. As such, in this embodiment of the invention, modification of the components of the dielectric layer, or the deposition conditions, or both, is temporary. That is, the modified state does not continue until deposition of the dielectric layer is complete, but rather, a return is made to the unmodified state before deposition of the dielectric layer is complete.

The interface between second dielectric sub-layer 30 and third dielectric sub-layer 28 is distinguished by a second non-discrete transitional sub-layer 26. The composition of second non-discrete transitional sub-layer 26 varies through its thickness from a composition substantially the same as second dielectric sub-layer 30 where it contacts second dielectric sub-layer 30 to a composition substantially the same as third dielectric sub-layer 28 where it contacts third dielectric sub-layer 28, the change in composition being gradual within second non-discrete transitional sub-layer 26.

Together, first dielectric sub-layer 20, first non-discrete transitional sub-layer 24, second dielectric sub-layer 30, second non-discrete transitional sub-layer 26, and third dielectric sub-layer 28 comprise dielectric layer 40.

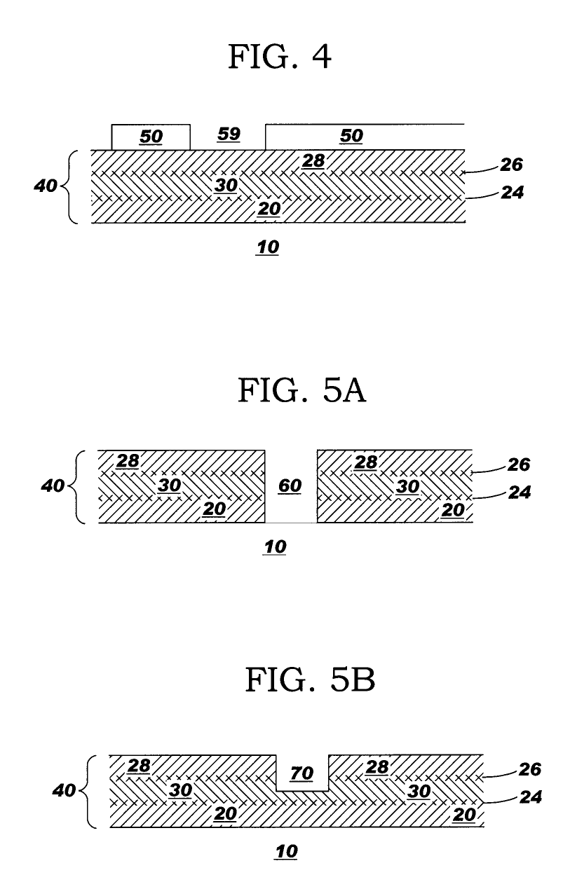

FIGS. 4-5B illustrate steps for forming an opening 60 (FIG. 5A), 70 (FIG. 5B) in a semiconductor according to a first embodiment of the invention. Referring to FIG. 4, a photoresist layer 50 has been deposited onto dielectric layer 40 and an opening 54 patterned into photoresist layer 50.

FIGS. 5A-5B illustrate how varying the etch recipe allows formation of different structures in the dielectric layer. Referring to FIG. 5A, an etch recipe has been applied that is selective to neither first dielectric sub-layer 20, third dielectric sub-layer 28 nor second dielectric sub-layer 30, resulting in an opening 60 in dielectric layer 40 through to substrate 10. That is, opening 60 extends no deeper than the sub-layer nearest substrate 10. Such an opening may be used, for example, to form a structure such as a via.

Referring to FIG. 5B, an etch recipe has been applied that is selective to second dielectric sub-layer 30, but that will etch first dielectric sub-layer 20 and third dielectric sub-layer 28, resulting in an opening 70 in dielectric layer 40 extending only through third dielectric sub-layer 28. Such an opening may be used, for example, to form a structure such as a trough.

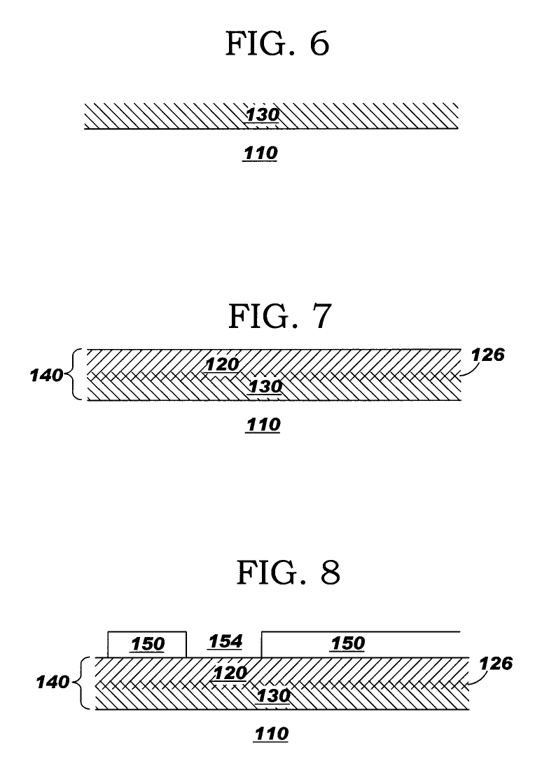

FIGS. 6-7 illustrate steps in the formation of a semiconductor device according to a second embodiment of the invention, wherein the dielectric layer is comprised of two sub-layers, rather than three, as in a first embodiment, and wherein the order of deposition of the etch-resistant and etchable sub-layers is reversed from that of the first embodiment. Referring to FIG. 6, an etch-resistant dielectric sub-layer 130 resides directly atop substrate 110. Etch-resistant dielectric sub-layer 130 is analogous to second dielectric sub-layer 30 in the first embodiment of the invention, described above.

Referring to FIG. 7, without stopping the deposition of the dielectric layer, the etch properties of the dielectric layer are altered by modifying the components of the dielectric layer, or the deposition conditions, or both. The resulting etchable dielectric sub-layer 120 has etch properties different than etch-resistant dielectric sub-layer 130, and is analogous to first dielectric sublayer 20 in a first embodiment of the invention, described above. The interface between etch-resistant dielectric sub-layer 130 and etchable dielectric sub-layer 120 is distinguished by a non-discrete transitional sub-layer 126. The composition of non-discrete transitional sub-layer 126 varies through its thickness from a composition substantially the same as etch-resistant dielectric sub-layer 130 where it contacts etch-resistant dielectric sub-layer 130 to a composition substantially the same as etchable dielectric sub-layer 120 where it contacts etchable dielectric sub-layer 120, the change in composition being gradual within non-discrete transitional sub-layer 126.

Together etch-resistant dielectric sub-layer 130, non-discrete transitional sub-layer 126, and etchable dielectric sub-layer 120 form dielectric layer 140.

In one embodiment, etchable dielectric sub-layer 120 is more susceptible to etching than etch-resistant dielectric sub-layer 130, the latter of which effectively forms an etch stop layer within dielectric layer 140. In one embodiment, etch resistance is decreased in etchable dielectric sub-layer 120 by, for example, decreasing its carbon content, or fluorine content, or both. A decrease in carbon content, for example, results in a general increase in etch rate. And, since typical etch processes use fluorocarbon gasses (e.g., CF₄, CHF₃, CH₂F₂, C₄F₈, etc.), the substitution of hydrogen atoms for fluorine atoms in the dielectric layer will similarly result in an increased etch rate. Thus, a decrease in etch resistance and formation of an etch stop layer beneath an etchable dielectric sub-layer can be achieved by modifying the composition of the dielectric layer, or the deposition conditions, or both.

In this embodiment, since etch-resistant sub-layer 130 is deposited first, modification of the composition of the dielectric layer may include the removal of organic alkoxysilanes, alkylsiloxanes, and their fluoro-substituted analogs. In one embodiment, such compounds may include, for example, methylsilane, dimethylsilane, trimethylsilane, trifluoromethylsilane, 1,2-disilanotetrafluorethylene, 1,3-bis(silanodifluoromethylene)disiloxane, 2,2-disilanohexafluorosilane, bis(trifluoromethyldisiloxanyl)difluormethane, octamethylcyclotetrasiloxane, and tetramethylcyclotetrasiloxane. Modification of the deposition conditions may be as stated above relative to the first embodiment.

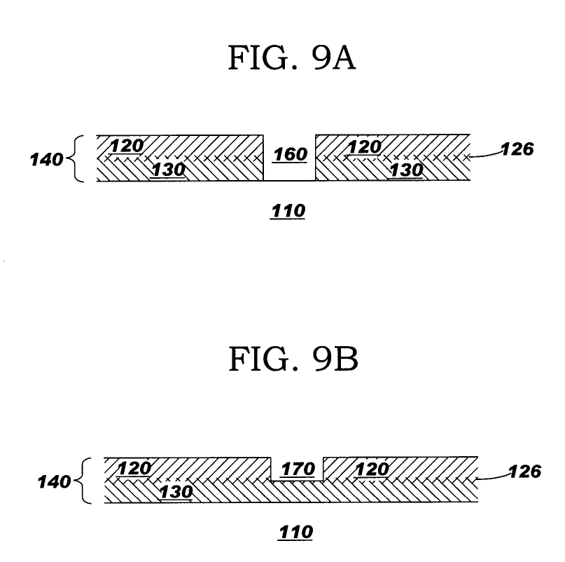

FIGS. 8-9B illustrate steps of forming an opening 160 (FIG. 9A), 170 (FIG. 9B) in a semiconductor according to a second embodiment of the invention. Referring to FIG. 8, a photoresist layer 150 has been deposited onto dielectric layer 140 and an opening 154 patterned into photoresist layer 150. FIGS. 9A-9B illustrate how varying the etch recipe allows formation of different structures within the dielectric layer. Referring to FIG. 9A, an etch recipe has been applied that is selective to neither etchable dielectric sub-layer 120 nor etch-resistant dielectric sub-layer 130, resulting in an opening 160 in dielectric layer 140 through to substrate 110. Such an opening may be used, for example, to form a structure such as a via.

Referring to FIG. 9B, an etch recipe has been applied that is selective to etch-resistant dielectric sub-layer 130, but that will etch etchable dielectric sub-layer 120, resulting in an opening 170 in dielectric layer 140 extending only through etchable dielectric sub-layer 120. That is, opening 170 extends no deeper than the sub-layer nearest substrate 110. Such an opening may be used, for example, to form a structure such as a trough.

The invention includes, as described above in connection with the first and second embodiments, a method of forming at least one opening in the dielectric layer. The method comprises the steps of continuously depositing a dielectric layer onto a substrate, modifying at least one of a dielectric layer composition and a deposition condition, and forming an opening in the dielectric layer. The properties of the modified and unmodified dielectric sublayers that result enable the formation of various openings in the dielectric layer.

In either the first or second embodiment above, using an etch recipe selective to neither sub-layer enables the formation of an opening in the dielectric layer that may extend to the substrate. It is also possible, through the use of particular etch recipes, to form an opening in the dielectric layer that extends to a depth not greater than a depth at which the at least one of the dielectric layer composition and the deposition condition were not modified. In the first embodiment of the invention, this may be accomplished, for example, by using an etch recipe selective to the modified sub-layer but capable of etching the unmodified sub-layer. In the second embodiment of the invention, this may be accomplished, for example, by using an etch recipe selective to the unmodified sub-layer but capable of etching the modified sub-layer.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. A semiconductor device comprising:
a substrate;
a dielectric layer atop the substrate, the dielectric layer including a first sub-layer, a second sub-layer and a first non-discrete transitional sub-layer residing between the first and second sub-layer, wherein the first sub-layer has an etch resistance different than the second sub-layer; and
an opening extending no deeper than the sub-layer nearest the substrate.

2. The semiconductor device according to claim 1, wherein an etch resistance of the first sub-layer is greater than an etch resistance of the second sub-layer.

3. The semiconductor device according to claim 1, wherein the first sub-layer has a greater content of at least one of carbon and fluorine than the second sub-layer.

4. The semiconductor device according to claim 1, wherein the first sub-layer includes at least one component not included in the second sub-layer, the at least one component being selected from a group consisting of fluoroalkylsilanes, fluoralkylsiloxanes, perfluoroalkylsilanes, perfluoroalkylsiloxanes, alkylsilanes, and alkylsiloxanes.

5. The semiconductor device according to claim 4, wherein the at least one component is selected from a group consisting of methylsilane, dimethylsilane, trimethylsilane, trifluoromethylsilane, 1,2-disilanotetrafluorethylene, 1,3-bis(silanodifluoromethylene)disiloxane, 2,2-disilanohexafluorosilane, bis(trifluoromethyldisiloxanyl)difluormethane, octamethylcyclotetrasiloxane, and tetramethylcyclotetrasiloxane.

6. The semiconductor device according to claim 1, wherein the dielectric layer includes a third sub-layer residing between the substrate and the first sub-layer and a second non-discrete transitional sub-layer residing between the third sub-layer and the first sub-layer.

7. The semiconductor device according to claim 6, wherein the second sub-layer and the third sub-layer have substantially the same etch resistance.

8. A method of modifying a dielectric layer during deposition, the method comprising the steps of:
continuously depositing a dielectric layer onto a substrate and
modifying at least one of a dielectric layer composition and a deposition condition during the depositing step.

9. The method of claim 8, wherein the modifying step includes removing at least one component of the dielectric layer composition, the component selected from a group consisting of fluoroalkylsilanes, fluoralkylsiloxanes, perfluoroalkylsilanes, perfluoroalkylsiloxanes, alkylsilanes, and alkylsiloxanes.

10. The method of claim 9, wherein the at least one component is selected from a group consisting of methylsilane, dimethylsilane, trimethylsilane, trifluoromethylsilane, 1,2-disilanotetrafluorethylene, 1,3-bis(silanodifluoromethylene)disiloxane, 2,2-disilanohexafluorosilane, bis(trifluoromethyldisiloxanyl)difluormethane, octamethylcyclotetrasiloxane, and tetramethylcyclotetrasiloxane.

11. The method of claim 8, wherein the modifying step is temporary.

12. The method of claim 11, wherein the modifying step includes adding at least one component to the dielectric layer composition, the component selected from a group consisting of fluoroalkylsilanes, fluoralkylsiloxanes, perfluoroalkylsilanes, perfluoroalkylsiloxanes, alkylsilanes, and alkylsiloxanes.

13. The method of claim 12, wherein the at least one component is selected from a group consisting of methylsilane, dimethylsilane, trimethylsilane, trifluoromethylsilane, 1,2-disilanotetrafluorethylene, 1,3-bis(silanodifluoromethylene)disiloxane, 2,2-disilanohexafluorosilane, bis(trifluoromethyldisiloxanyl)difluormethane, octamethylcyclotetrasiloxane, and tetramethylcyclotetrasiloxane.

14. The method of claim 8, wherein the deposition condition includes at least one of temperature, pressure, flow rate of dielectric layer components, and plasma power.

15. The method of claim 8, wherein the modifying step decreases at least one of the carbon content and fluorine content of the dielectric layer.

16. The method of claim 8, wherein the modifying step increases at least one of the carbon content and the fluorine content of the dielectric layer.

17. A method of forming at least one opening in a dielectric layer, the method comprising the steps of:
continuously depositing a dielectric layer onto a substrate;
modifying at least one of a dielectric layer composition and a deposition condition; and
forming an opening in the dielectric layer.

18. The method of claim 17, wherein the modifying step is temporary.

19. The method of claim 17, wherein the opening extends to the substrate.

20. The method of claim 17, wherein the opening extends to a depth not greater than a depth at which the at least one of the dielectric layer composition and the deposition condition were not modified.
